(19) United States
(12) Patent Application Publication
(10) Pub. No.: US 2025/0040324 A1
(43) Pub. Date: Jan. 30, 2025

(54) LIGHT EMITTING DEVICE AND DISPLAY DEVICE

(71) Applicant: Brian Kim, Gyeonggi-do (KR)

(72) Inventor: Brian Kim, Gyeonggi-do (KR)

(21) Appl. No.: 18/786,430

(22) Filed: Jul. 26, 2024

Related U.S. Application Data
(60) Provisional application No. 63/529,716, filed on Jul. 29, 2023.

(51) Int. Cl. H01L 33/60; H01L 25/075; H01L 33/06; H01L 33/32; H01L 33/38; H01L 33/46; H01L 33/62

(52) U.S. Cl. CPC H01L 33/60; H01L 25/0753; H01L 33/06; H01L 33/32; H01L 33/387; H01L 33/46; H01L 33/62

(57) ABSTRACT

A light-emitting device includes a backplane, a light emitting diode (LED) emitter attached to the backplane, the LED emitter comprising an LED emitting stack that is made of a semiconductor material, and comprises an n-type region and a p-type region and a quantum well therebetween, and a light-reflecting partition attached to the backplane, wherein the light-reflecting partition is made of the semiconductor material, the light-reflecting partition forms a cavity surrounding the LED emitter, and a surface of the light-reflecting partition is coated with a first reflective layer.

### CROSS REFERENCE TO RELATED APPLICATIONS

This application claims priority to U.S. Provisional Patent Application Ser. No. 63/529,716 filed on Jul. 29, 2023. The contents of the application are incorporated herein by reference in its entirety.

### TECHNICAL FIELD

The present disclosure relates to light-emitting devices and display devices, and particularly to LED emitters with light-reflecting partitions and methods of fabricating the same.

### BACKGROUND

Light-emitting diode displays (hereafter light-emitting devices) are a type of direct-view display in which the subpixel elements themselves emit photons, and are used in electronic displays such as backlighting for liquid crystal displays in laptops and televisions, LED billboards, microdisplays, and LED televisions.

A display device, such as a direct-view display may be formed from an ordered array of pixels. Each pixel may include a set of subpixels that emit photons at a respective wavelength.

For example, a pixel may include a red subpixel, a green subpixel, and a blue subpixel. Each subpixel may include one or more LED emitters with different sizes and geometries.

Each pixel may be driven by backplane circuitry to display any combination of colors within a color gamut.

The display panel may be formed by a process in which LED emitters are soldered to, or otherwise electrically attached to, a bond pad located on a backplane. The bond pad is electrically driven by the backplane circuit and other driving electronics.

Recent advances in LED technology have led to the development of micro- and nano-sized LEDs, which are smaller than traditional LEDs, and are being used in augmented reality (AR) and virtual reality (VR) display system.

A typical micro-LED emitter has lateral dimensions ranging from 1 to 150 micrometers. LED emitters smaller than 1 micrometer in size are called nanorods (also known as nanowires, nanocolumns, and nanopillers), which can range in size from tens to hundreds of nanometers.

The application of micro-sized LED emitters in array forms as displays has been attempted for a long time. Early attempts did not insert a medium between the LED emitters and left them free space, so photons could not effectively radiate to the front of the LED emitters and leaked laterally to adjacent pixels, resulting in optical crosstalk and lowering efficiency. To prevent this, a reflective layer was proposed to be attached to the LED sidewalls, but it was found to be insufficient to solve the existing technical issue. More recently, several methods have been proposed that place light-reflecting structures between the LED emitters.

FIG. 1A to 1D are various cross-sectional views and images of traditional LED display devices shown in the previously published papers and the patents, where the space between LED emitters does not have physical part blocking photon propagation.

FIG. 1A is a perspective view illustrating the structure of an embodiment of U.S. Pat. No. 6,410,940, entitled “Micro-size LED and Detector Arrays for Minidisplay, Hyper-Bright Light Emitting Diodes, Lighting and UV Detector and Image Sensor Applications.” granted to H. Jiang et al.

FIG. 1B is the structure and display image in a publication titled “Active matrix monolithic micro-LED full-color micro-display” in the Journal of Society for Information Display by Xu Zhang of the Hong Kong University of Science and Technology; and

FIG. 1C is a display image in a publication titled “MicroLED Display with LTPS Backplane using Novel Driving Circuit and Optical Outcoupling Structure” in IEEE Photonics Technology Letters by Z. Liu of Hong Kong University of Science and Technology. These suffer from the problem that photons generated by the selected (i.e., addressed) LED emitters P120 being waveguided to adjacent subpixels through the slab shaped n-type GaN layer, causing optical crosstalk.

The display image illustrated in FIG. 1C is an example of optical crosstalk in an LED display disclosed in a publication titled “Investigation of Forward Voltage Uniformity in Monolithic Light-Emitting Diode Arrays.” Unselected (i.e., unaddressed) subpixels should display the intensity of the black level, but optical crosstalk causes them to display intensity levels as if they were partially selected.

Recently, approaches such as the one shown in FIG. 1D have been actively proposed. Patents based on this concept include International Publication No. WO 2019/194931A1, U.S. Pat. No. 11,239,212, US Pub. No. 202000/66687A1, and US Pub. No. 2021/0193889.

In the case of FIG. 1D, the LED emitters are not connected by the slab shaped n-type GaN layer as in FIG. 1A and FIG. 1B, so the crosstalk between adjacent subpixels by waveguiding is eliminated, but there is other problem that the photons leaking through the sidewall of the LED emitter enter the adjacent pixels, causing optical crosstalk, which propagates laterally and disappears rather than being extracted to the front of the display device.

Subsequently, new approaches were proposed to directly enclosing the sidewall of the LED emitter with a metal film or dielectric mirror as shown in FIGS. 2A to 2C.

FIG. 2A is a drawing from U.S. Pat. No. 10,297,722, in which a reflective metallization encloses a mesa structure and a base structure comprising a p-n diode. FIG. 2B is a drawing from US 2016/0181476, in which a dielectric mirror encloses the p-n diode. FIG. 2C is a drawing from KR 2021/0026150, in which a reflective insulating layer encloses the micro-LED. The enclosing material may be a metal film, insulating layer, or dielectric mirror such as a distributed Bragg reflector (DBR), but the purpose is the same: to apply a light reflective material to the sidewall of the LED emitter to prevent light leakage through the sidewall.

While this sounds good in principle, in practice, the metal film is not 100% reflectivity, so photon loss by absorption increases exponentially as photons travel through the GaN space and repeatedly hit the light-reflective layer until they are extracted into the air through the front surface of the LED emitter. Since GaN has a high refractive index of 2.378 at 632.8 nm, the contrast of the refractive index at the interface with air is high, and the photons repeatedly hit with the sidewall multiple times by internal total reflection. In addition, dielectric mirrors are not a realistic option because they must be stacked in tens to hundreds of layers of different refractive indices, each a wavelength (λ/4) thickness, to act as an effective reflector. As a result, the thickness became too thick to be practical for small sizes such as microLEDs.

Finally, to address these issues, a method had been proposed that introduces partitions between adjacent LED emitters, as shown in FIG. 3A to 3C.

FIG. 3A is a drawing from U.S. Pat. No. 11,404,400, in which an epitaxial p-n diode layer comprising an n-doped layer, an active layer, and a p-doped layer is surrounded by a well structure 160, comprising an insulator and a reflective layer. FIG. 3B is a structure in which a reflector surrounds LED emitters, according to a paper published by Kyocera at Proceedings of the International Display Workshops (2020). FIG. 3C is a drawing from a paper published in Nature, Light: Science & Applications (2015) showing that a structure called “Regrown n-GaN” is formed between the emitters and the surface is coated with aluminum.

In addition to this, there are other patent applications with the same inventive concept, such as U.S. Pat. Nos. 10,685,940, 10,868,048, WO 2021/033775A1, and U.S. Pat. No. 10,734,440.

What the above methods have in common is that the photons emitted outside the LED emitter are reflected from the reflective layer on the surface of the partition, preventing optical crosstalk and increasing the efficiency of photon utilization.

Despite the above effects, all methods have in common that they require additional processes to form the partitions, which not only increases the cost but also hinders the implementation of high resolution. More importantly, semiconductors for p-n diodes are easily degraded by contamination and damage when post-processing is added.

### BRIEF SUMMARY

According to an aspect of the present disclosure, a sub-pixel element of a light-emitting device includes a backplane, an array of LED light emitters, and a light reflective partition attached to a front surface of the backplane, wherein the LED light emitters comprise a stack of doped semiconductor layers comprising p-n diodes, and the light-reflecting partition is coated with a reflective layer.

The light-reflecting partition includes a conductive layer for electrical contact between the n-contact of LED emitters and the n-pads of the backplane or between the p-contact of LED emitters and the p-pads of the backplane.

According to one aspect of the present disclosure, the material comprising the light-reflecting partition is made of the same material as the LED emitter and has a reflective layer on its surface.

The light-reflecting partition may have the advantage of being formed without additional processing, and a cost-effective high performance and a high-resolution display device can be realized.

In one another aspect, a light-emitting device includes a backplane, a light emitting diode (LED) emitter attached to the backplane, the LED emitter comprising an LED emitting stack that is made of a semiconductor material, and comprises an n-type region and a p-type region and a quantum well therebetween, and a light-reflecting partition attached to the backplane, wherein the light-reflecting partition is made of the semiconductor material, the light-reflecting partition forms a cavity surrounding the LED emitter, and a surface of the light-reflecting partition is coated with a first reflective layer.

The light-emitting device may further include a plurality of LED emitters arranged in an array, and a plurality of light-reflecting partitions arranged in a grid configuration.

Each of the plurality of light-reflecting partitions may form a cavity surrounding one of the plurality of LED emitters, wherein the cavity is left as a free space or filled with a transparent polymer encapsulation material or a color conversion material.

The first reflective layer may be made of a light-reflective metallic film or a material of the inorganic powder including titanium dioxide (TiO₂).

The first reflective layer coated on each light-reflective partition may be electrically conductive.

A height of the plurality of LED emitters may be the same as or lower than a height of the plurality of light-reflective partitions.

The light-emitting device may further include a second light-reflective layer formed on a top surface of the LED emitter.

A shape of the second light-reflective layer may include one of various geometric shapes including a flat shape, concave shape, convex shape, and combinations thereof.

The second reflective layer may cover an n-contact of the LED emitter when the n-region is disposed at the top and the p-region is disposed at the bottom.

In the light-emitting device, the second reflective layer may cover an entire upper part of the LED emitter.

In the light-emitting device, a lens array may be located on top of the LED array.

In the light-emitting device, the color conversion layer may be located on top of the LED array.

In the light-emitting device, both the color conversion layer and the lens array may be located on top of the LED array.

In the light-emitting device, a p-contact of the LED emitter may be attached to a p-pad of the backplane, and the n-contact of the LED emitter and the n-pad of the backplane are electrically connected by a conductive layer.

In the light-emitting device, an n-contact of the LED emitter is attached to the n-pad of the backplane, and the p-contact of the LED emitter and the p-pad of the backplane are electrically connected by a conductive layer.

In the light-emitting device, a nanoscale-to microscale optical collimator for collimation may be located on top of the color conversion layer.

In the light-emitting device, the optical collimator may be tapered in a downward direction.

In the light-emitting device, the optical collimator may have one of cross-sectional shapes including a circular or polygonal one, and a cross-section of a light exit portion thereof is wider than that of a light incident portion thereof.

### BRIEF DESCRIPTION OF DRAWINGS

FIGS. 1A to 1D show various cross-sectional views of traditional LED arrays for display devices with no partitions between adjacent LED emitters.

FIGS. 2A to 2C show prior art structures that directly enclosing the sidewalls of LED emitters with a reflective metal layer or dielectric mirror to prevent photons leakage through the sidewalls of the emitters.

FIG. 3A to 3C show the prior art structures of installing partitions between adjacent LED emitters and applying a light-reflective layer over the partitions to reflect while preventing photon leakage to adjacent LED emitters.

FIGS. 4A and 4B are exemplary top and vertical cross-sectional views of the LED array module according to one embodiment of the present disclosure.

FIG. 5A illustrates an LED sub-pixel, and FIG. 5B shows the equivalent circuit diagram of the LED sub-pixel according to one embodiment of the present disclosure.

FIG. 5C illustrates another LED sub-pixel, and FIG. 5D shows the equivalent circuit diagram of the LED sub-pixel according to another embodiment of the present disclosure.

FIGS. 6A to 6H are the manufacturing process flow diagram of FIGS. 4A and 4B, a representative embodiment of the present disclosure.

FIGS. 7A and 7B are exemplary top and vertical cross-sectional views of another embodiment of the present disclosure.

FIGS. 8A to 8D are exemplary vertical cross-sectional views illustrating the effect of a reflective layer applied to the top surface of the light-reflecting partition composed of a stack of doped semiconductor layers, according to embodiments of the present disclosure.

FIGS. 9A to 9D are exemplary vertical cross-sectional views illustrating the effect of a reflective layer applied to the top surface of an LED emitter according to embodiments of the present disclosure.

FIGS. 10A to 10D are exemplary vertical cross-sectional views illustrating various embodiments in combination with a color conversion material or collimation lens according to the ideas of the present disclosure.

FIGS. 11A and 11B are another embodiment of the present disclosure with nano- to microscale optical components for collimation installed on top of the color conversion layer.

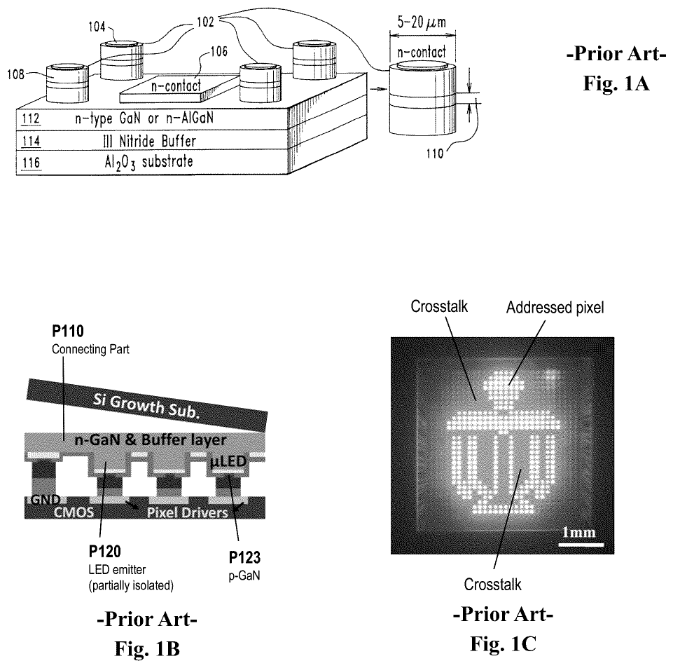

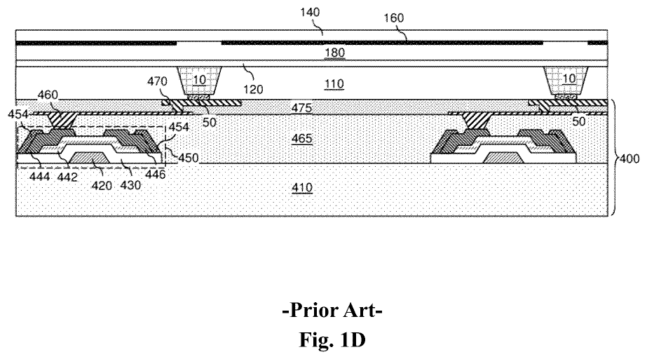

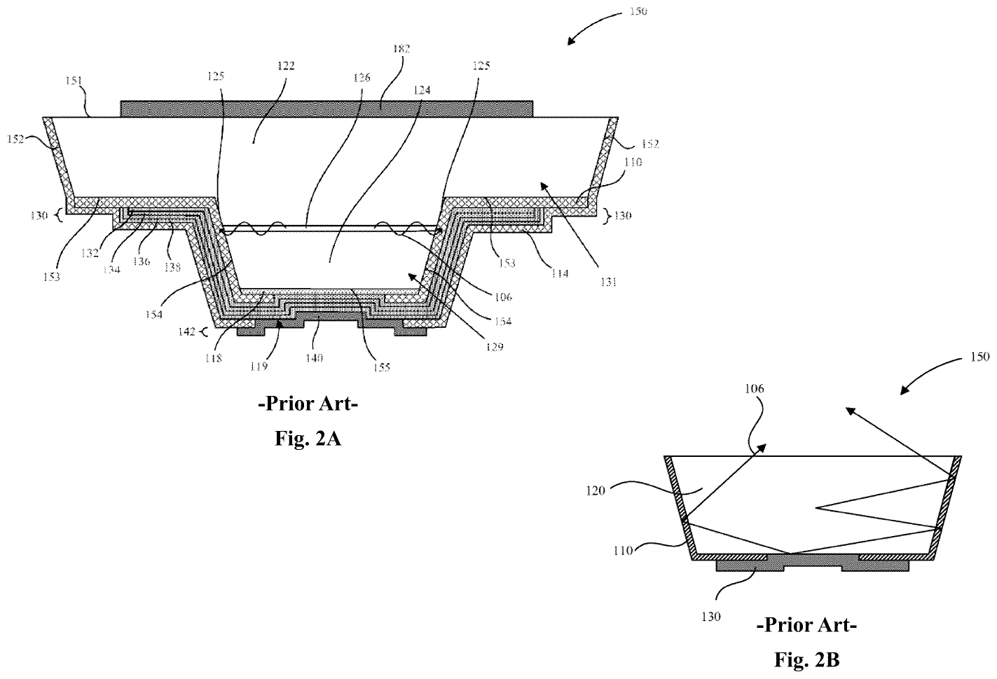

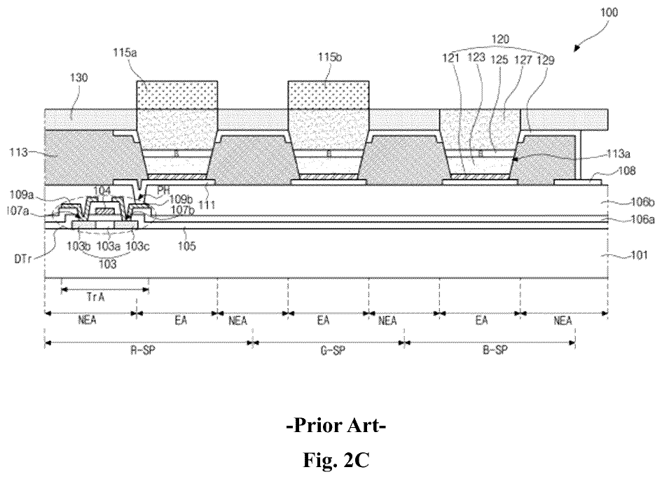

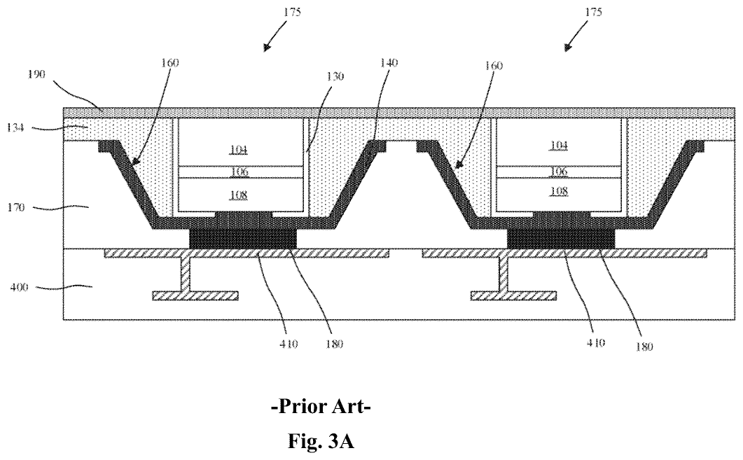

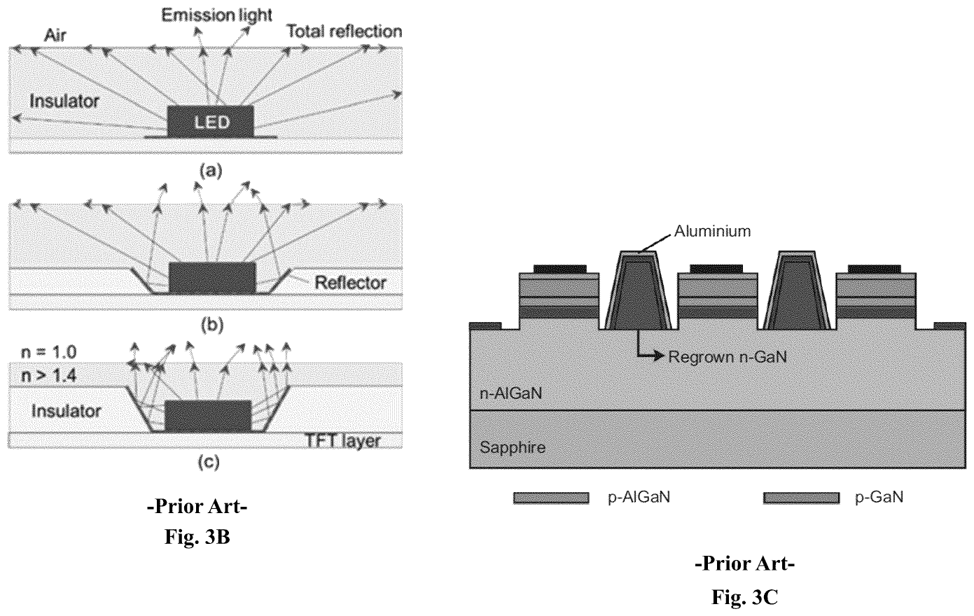

### DETAILED DESCRIPTION

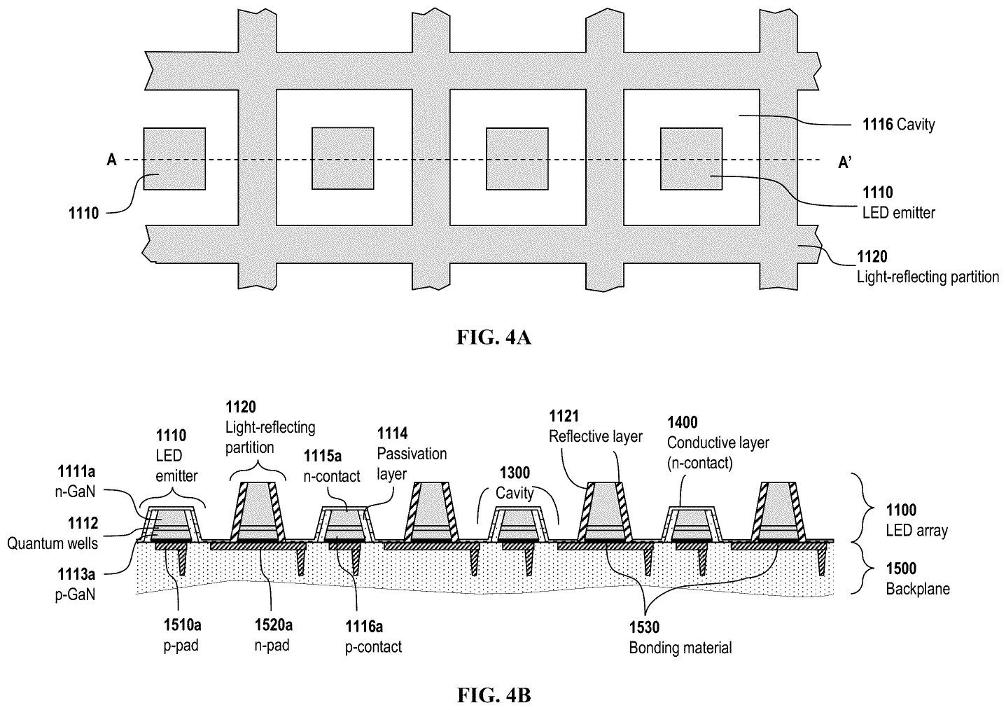

FIGS. 4A to 11, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged system and method. The following description with reference to the accompanying drawings is provided to assist in a comprehensive understanding of various embodiments of the present disclosure as defined by the claims and their equivalents. It includes various specific details to assist in that understanding but these are to be regarded as mere examples. Accordingly, those of ordinary skill in the art will recognize that various changes and modifications of the various embodiments described herein can be made without departing from the scope and spirit of the present disclosure. In addition, descriptions of well-known functions and constructions may be omitted for clarity and conciseness.

It should be apparent to those skilled in the art that the following description of various embodiments of the present disclosure is provided for illustration purpose only and not for the purpose of limiting the present disclosure as defined by the appended claims and their equivalents.

Although ordinal numbers such as “first,” “second,” and so forth will be used to describe various components, those components are not limited herein. The terms are used only for distinguishing one component from another component. For example, a first component may be referred to as a second component and likewise, a second component may also be referred to as a first component, without departing from the teaching of the inventive concept.

The terminology used herein is for the purpose of describing various embodiments only and is not intended to be limiting. As used herein, the singular forms are intended to include the plural forms as well, unless the context clearly indicates otherwise. It will be further understood that the terms “comprises” and/or “has,” when used in this specification, specify the presence of a stated feature, number, step, operation, component, element, or a combination thereof, but do not preclude the presence or addition of one or more other features, numbers, steps, operations, components, elements, or combinations thereof.

FIG. 4A is an exemplary top view of the LED array module according to one embodiment of the present disclosure.

As shown in FIG. 4A, the present disclosure provides the LED array module for a display device with high luminous efficiency by installing a light-reflecting partition 1120 between LED emitters 1110 to prevent optical crosstalk.

The present disclosure prevents an optical crosstalk and a luminous efficiency reduction caused by the propagation of photons emitted through the sidewall of the LED emitter to adjacent pixels.

Furthermore, the coupling efficiency between the micro-lens array (MLA) and display devices can be improved by the collimation of photons by the appropriate geometric design of the light-reflecting partition 1120.

One feature that makes the present disclosure different from the prior art is that it utilizes the semiconductor layer formed by the epitaxial process itself to build the LED light emitter 1110 and the light-reflecting partition 1120 together, eliminating the need for an additional process to build the light-reflecting partition 1120. Thus, unlike the prior art, no additional process for building the light-reflecting partition 1120 is required, thereby simplifying the process, which is advantageous in terms of cost, yield, performance and enabling the realization of a high-resolution LED array.

In particular, the display device may comprise a plurality of LED emitters 1110, and a plurality of light-reflecting partitions 1120. Each light-reflecting partition 1120 forms a cavity 1300 surrounding the LED emitter 1110. As shown in the top view, the light-reflecting partition 1120 may have a grid-like shape for each sub-pixel. The space inside the cavity 1300 can be left free, filled with an encapsulation material 1700 made of a transparent polymer, or filled with a color conversion material 1605.

FIG. 4B is an exemplary vertical cross-sectional view of the LED array module along line A-A′ of FIG. 4A.

Each LED emitter 1110 comprises an LED emitting stack made of a semiconductor material, such as gallium nitride. The LED emitting stack may include a quantum well with n-type region and p-type region.

The height of the LED emitter 1110 can be made the same as or lower than that of light reflecting partition 1120 by controlling the process conditions of the etching process. The effect of lowering the height of the LED emitter 1110 is that the radiation angle of photons reflected by the light-reflecting partition 1120 is collimated more effectively. In addition, in this case, the inside the cavity 1300 formed by the light-reflecting partition 1120 can be filled with transparent materials having various refractive indices to promote light extraction. It is also possible to fill the inside the cavity 1300 with a color conversion material 1605, such as a quantum dot or phosphor, so that the photons radiated from the LED emitter can efficiently interact with the color conversion material. Additionally, it is possible to increase color purity by reducing direct radiation into the air from the top surface of the LED emitter 1110.

Furthermore, by applying the reflective layer 1410 to the top surface of the LED emitter, it is possible to enhance the radiation of photons through the LED sidewall so that the photons can further interact with the color conversion material 1605. In this case, the shape of the top reflective layer 1410 of the LED emitter 1110 can be made in various shapes such as not only flat, but also concave or convex and combinations thereof, to maximize radiation from the sidewall.

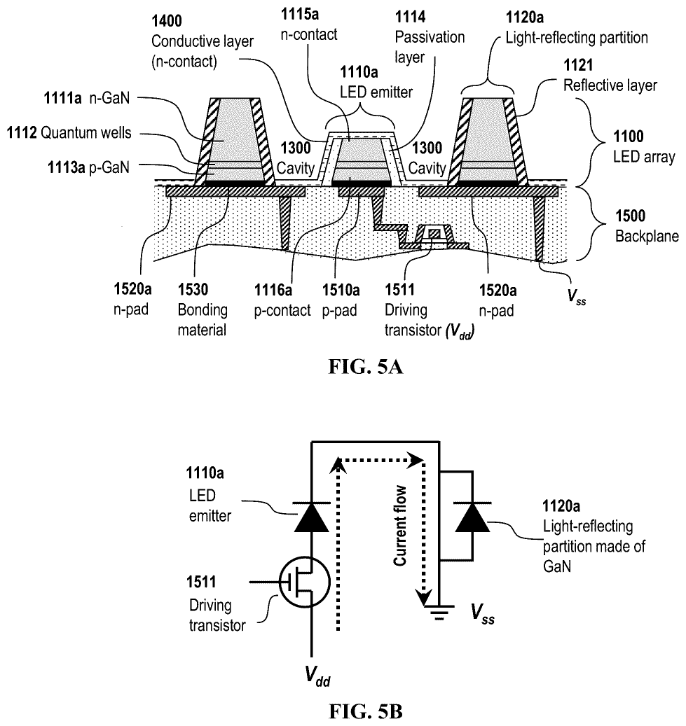

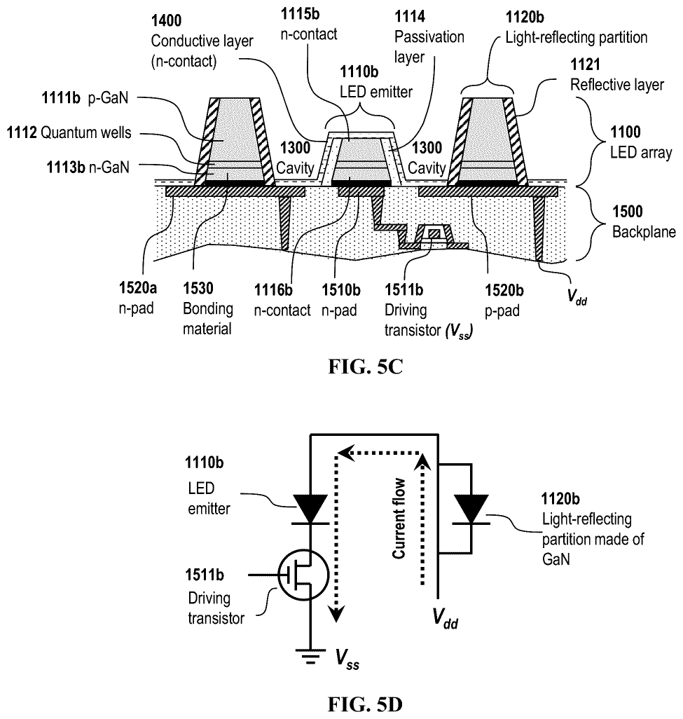

FIG. 5A illustrates one sub-pixel of the LED array of FIG. 4B, and FIG. 5B illustrates the equivalent circuit diagram of the LED sub-pixel of FIG. 5A.

LED emitter 1110a comprises an LED emitting stack made of a semiconductor material, such as gallium nitride (GaN). The LED emitting stack may include the n-type region (e.g., n-GaN 1111a) at the top and the p-type region (e.g., p-GaN 1113a) at the bottom and the quantum well 1112 therebetween.

Each LED emitter 1110a may be connected to the p-pad 1510a of the backplane 1500 via the p-contact 1116a, and the n-contact 1115a, which is the top surface of the LED emitter 1110a, is connected to the n-pad 1520a of the backplane 1500 via the conductive layer 1400. The p-pad 1510a is connected to the driving transistor 1511a powered by a voltage source Vdd. The sidewalls of the LED emitters are electrically isolated by applying the passivation layer 1114.

The light-reflecting partition 1120a may be made of the same material as the LED emitter 1110a, and a reflective layer 1121 is applied to its surface for the purpose of reflecting light. The light-reflecting partition 1120a may be connected to the n-pad 1520a of the backplane 1500 via the bonding material 1530.

The light-reflecting partition 1120a may be made of the same semiconductor material as the LED emitter 1110a in the form of a p-n diode.

A reflective layer 1121, which is conductive, may be applied to its surface, and a conductive layer 1400 is applied on top of it to electrically connect with the n-contact 1115a of the LED emitter 1110a. Thus, an equivalent circuit diagram as shown at FIG. 5B is constructed.

The light-reflecting partition 1120a may include a p-n diode, but since both ends are connected by conductors and there is no potential difference (i.e., no voltage is applied to the p-n diode). Therefore, when the LED emitter 1110a is turned on, current does not flow to the p-n diode of the light-reflecting partition 1120a, but instead flows to the n-pad 1520a through the reflective layer 1121 and conductive layer 1400. The n-pad 1520a is grounded to ground Vss. As a result, the light-reflecting partition 1120a serves only as a structure for reflecting light.

FIG. 5C illustrates another example sub-pixel of the LED array according to one embodiment of the present disclosure. In this embodiment, the locations of the n-type regions and p-type regions are reversed compared to the embodiment illustrated in FIG. 5A. The equivalent circuit diagram of the LED sub-pixel of FIG. 5C is shown in FIG. 5D.

Thus, LED emitter 1110b comprises p-GaN 1111b at the top and the n-GaN 1113b at the bottom and the quantum well 1112 therebetween. Each LED emitter 1110b may be connected to the n-pad 1510b of the backplane 1500 via the n-contact 1116b, and the p-contact 1115b, which is the top surface of the LED emitter 1110b, is connected to the p-pad 1520b of the backplane 1500 via the conductive layer 1400. The n-pad 1510b is connected to the driving transistor 1511b to maintain the ground (voltage) Vss.

The light-reflecting partition 1120b may be connected to the p-pad 1520b of the backplane 1500 via the bonding material 1530. The p-pad 1520b is grounded to ground Vss.

Since both ends of the light-reflecting partition 1120b are connected by conductors, there is no potential difference between both ends of the p-n diode of the light-reflecting partition 1120b (i.e., no voltage is applied to the p-n diode). Therefore, when the LED emitter 1110b is turned on, the current does not flow to the p-n diode of the light-reflecting partition 1120b, but instead flows to the driving transistor 1511b through the reflective layer 1121 and the conductive layer 1400. The driving transistor 1511b is connected to ground Vss. As a result, the light-reflecting partition 1120b serves only as a structure for reflecting light.

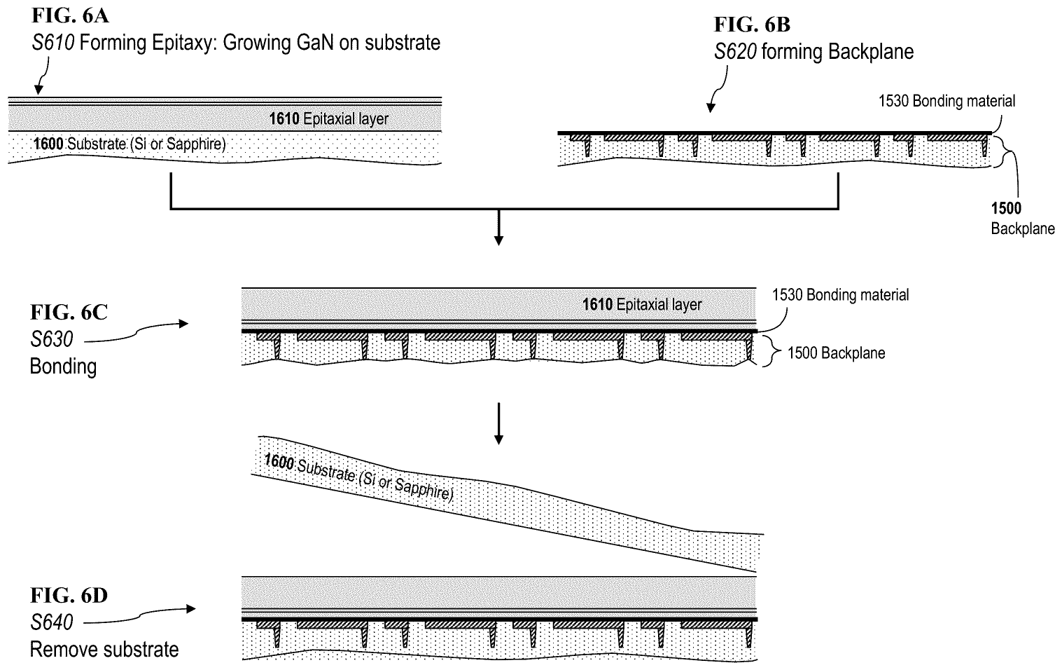

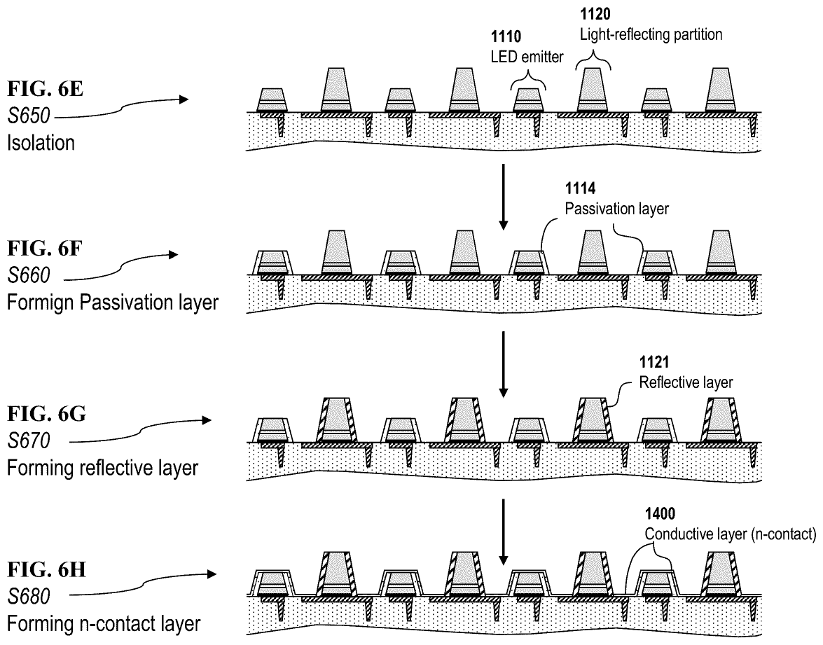

FIG. 6A to 6H illustrate an example of a manufacturing process flow diagram for the LED array module according to one embodiment of the present disclosure.

FIG. 6A illustrates step S610 of forming a semiconductor epitaxial layer 1610 by metal organic chemical vapor deposition (MOCVD) or molecular beam epitaxy (MBE) process on a silicon, sapphire, or other template substrate 1600.

FIG. 6B illustrates step S620 of forming a backplane 1500. The backplane 1500 includes circuitry formed on a substrate material of a silicon, glass, or plastic substrate.

FIG. 6C illustrates step S630 of bonding the epitaxial layer 1610 to the backplane 1500 using a bonding material 1530.

FIG. 6D illustrates step S640, in which the substrate 1600 may be removed by a laser lift-off (LLO) or chemical etch process.

After that, an isolation process may be performed to fabricate the LED light emitter 1110 and the light reflective partition 1120 together, as shown in FIG. 6E. In general, plasma etching with inductively coupled plasma (ICP) is more widely used than wet etching.

Then, a passivation layer 1114 may be applied to protect the sidewall of the LED emitter 1110, as shown in FIG. 6F. Applicable passivation layers include SiO₂ or Al₂O₃ with atomic layer deposition (ALD), chemical vapor deposition (CVD) and sputtering process.

Then, a reflective layer 1121 may be applied to the surface of the light-reflecting partition 1120, as shown in FIG. 6G, and a conductive layer 1400 may be applied to electrically connect the n-contact 1115a of the LED emitter 1110 and the n-pad 1520a of the backplane 1500, as shown in FIG. 6H. Applicable conductive layer includes metals, conductive oxide such is Indium Tin Oxide (ITO) and conductive polymers.

As a backend process, an encapsulation material 1700, a color conversion material 1605, a black layer 1800, a lens array 1900, and a color filter may be formed, but are not shown in the drawings.

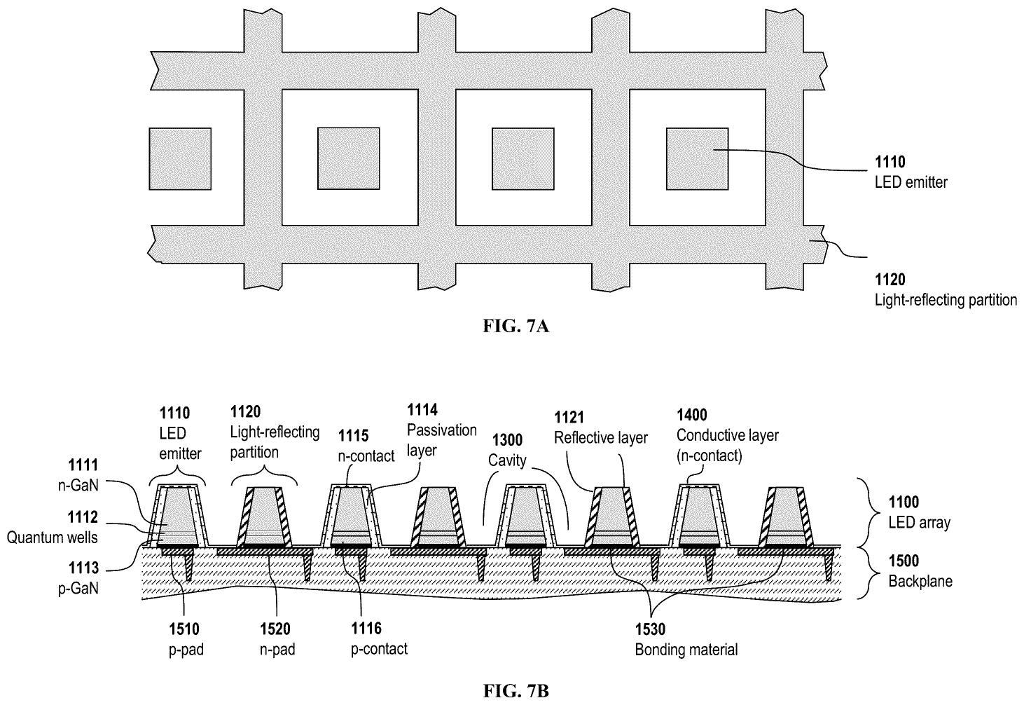

FIGS. 7A and 7B illustrate another example of an LED array module of FIG. 4B, according to one embodiment of the present disclosure. In FIG. 4B, the height of the LED emitters is lower than the height of the light reflecting partitions, but in this embodiment in FIG. 7B, the height of the LED emitters 1110 and height of the light reflecting partitions 1120 are the same.

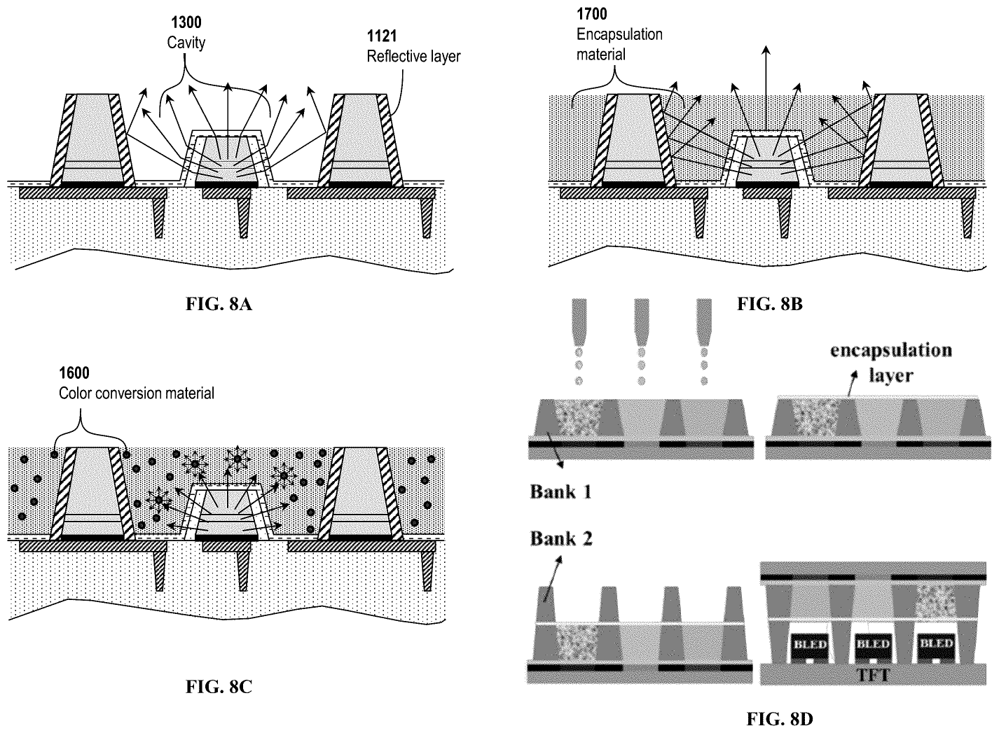

FIGS. 8A to 8D illustrates various effects of cavity 1300 according to embodiments of the present disclosure.

FIG. 8A is the case of free space where nothing is filled the space inside the cavity 1300. In this case, the refractive index when the LED emitter 1110 is composed of GaN is 2.38 at 632.8 nm, so the contrast of the refractive index at the interface with air is high.

Therefore, the photons emitted by the LED emitter 1110 are refracted at a large angle at the GaN/air interface as shown in the figure, and only some photons reach the reflective layer 1121 and are reflected.

FIG. 8B illustrates an embodiment, in which the space inside the cavity 1300 is filled with encapsulation material 1700. Materials such as transparent polymers or silicones typically have a refractive index of 1.4 to 1.6.

Therefore, the contrast of refractive index is smaller than in free space (i.e., air), and the angle of refraction at the interface is smaller, allowing a greater number of photons to reach the reflective layer 1121 and be reflected. This increases the number of photons that reach the reflective layer 1121, which is useful for collimation because more reflections can effectively change the direction of photon propagation.

Recently, high refractive index polymers with a refractive index of around 2 have become commercially available. Filling the space inside the cavity 1300 with these such high refractive index materials further reduces the angle of refraction of the photons, allowing more photons to reach the reflective layer 1121 and multiplying the collimation effect.

FIG. 8C illustrates the effect when the space inside the cavity 1300 is filled with color conversion material 1605. Typically, the color conversion material 1605 may be disposed on top of the LED emitter 1110, as shown in FIG. 8D.

However, in the embodiment of the present disclosure, by applying the color conversion material 1605 directly inside the cavity 1300, the color conversion material 1605 comes into contact with the sidewall as well as the top surface of the LED emitter 1110, thereby maximizing color conversion efficiency. Currently, the most widely used color conversion material 1605 is quantum dot, a powder with a particle size of nanometer, which is applied by mixing with a solution or polymer. Thus, dispersing the color conversion material 1605 in a high refractive index polymer can increase the conversion efficiency by the effect shown in FIG. 8C.

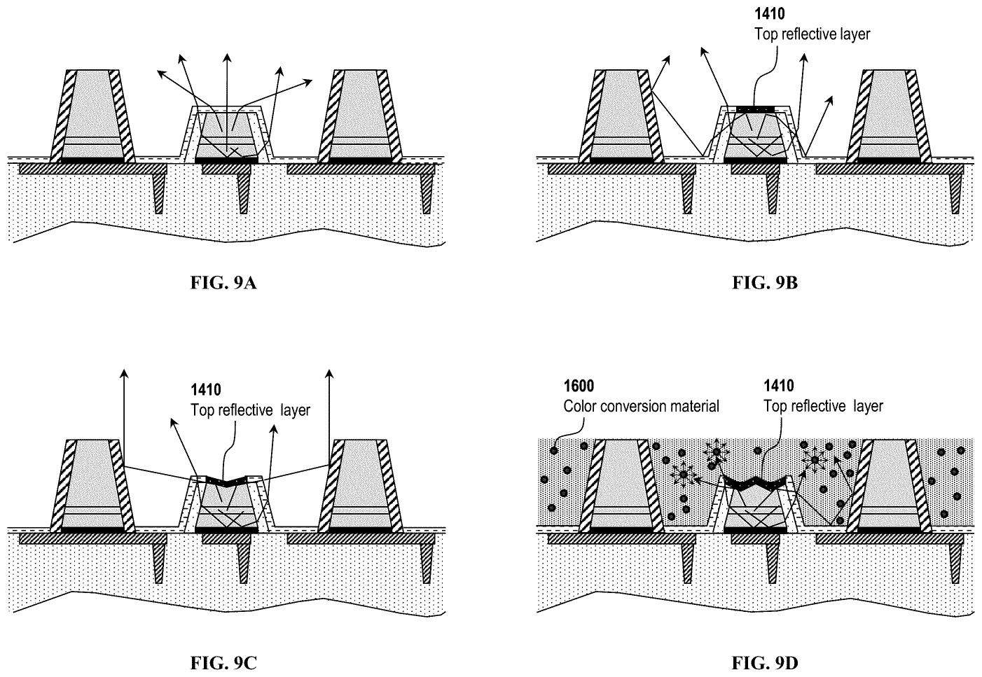

FIG. 9A to 9D illustrates various effects of applying the reflective layer 1410 to the surface of the LED emitter 1110, according to present disclosure.

FIG. 9A illustrates an embodiment where there is no reflective layer on the top surface of the LED emitter 1110. As illustrated, photons are easily radiated through the top surface of the LED emitter 1110.

FIGS. 9B-9D illustrate embodiments where the reflective layer 1410 is applied to the top surface of the LED emitter 1110. By applying the reflective layer 1410 to the top surface of the LED emitter, it is possible to enhance the radiation of photons through the LED sidewall so that the photons can further interact with the color conversion material 1605. In this case, the shape of the reflective layer 1410 of the LED emitter 1110 can be made in various shapes such as not only flat, but also concave or convex and combinations thereof, to maximize radiation from the sidewall.

As illustrated, photons are reflected by the top reflective layer 1410, and more photons are radiated in the lateral direction compared to FIG. 9A. The angle of the photons reflected by the top reflective layer 1410 depends on the geometry of the top reflective layer 1410.

FIG. 9C is an example of a case where the shape of the top reflective layer 1410 is concave, which shows that the photons are more effectively radiated in the lateral direction.

Although only a concave shape is illustrated, the top reflective layer 1410 can be formed in a variety of geometries, including convex shapes, and combinations thereof. Since the idea of the disclosure is to propagate more photons in the lateral direction by promoting scattering with the top reflective layer 1410, various geometries other than flat can be selected.

FIG. 9D is an illustration of the effect of the top reflective layer 1410 when the color conversion material 1605 is filled in the inside the cavity 1300. The presence of the top reflective layer 1410 promotes lateral propagation of photons, which can increase color conversion efficiency.

The top reflective layer 1410 can cover only the n-contact 1115a as shown in FIG. 9C, or the top reflective layer 1410 can cover the entire upper part of the LED emitter 1110 as shown in FIG. 9D.

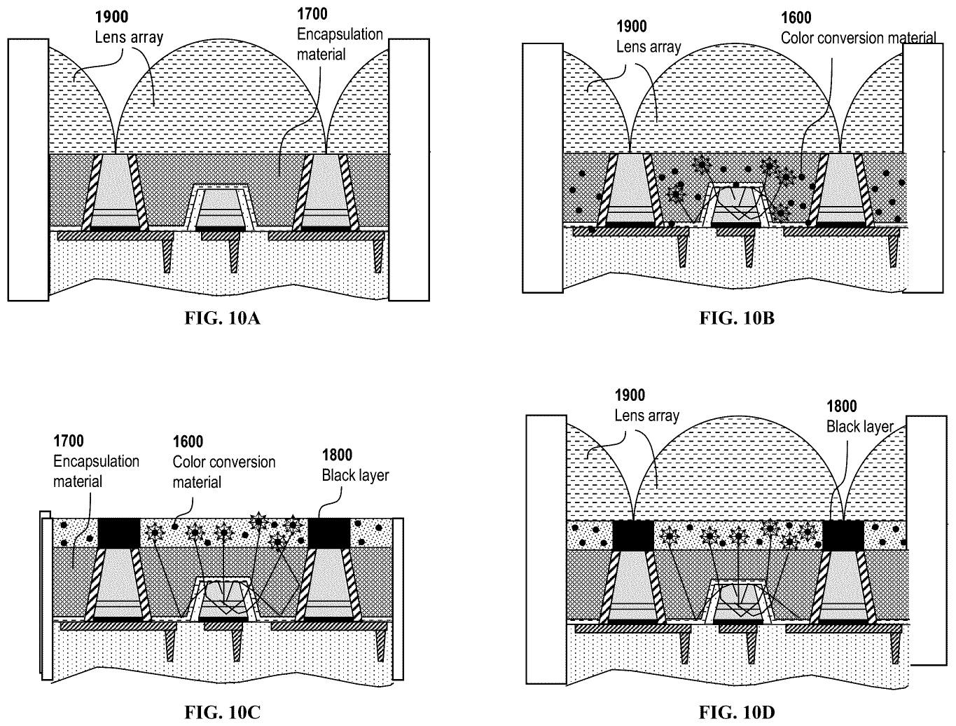

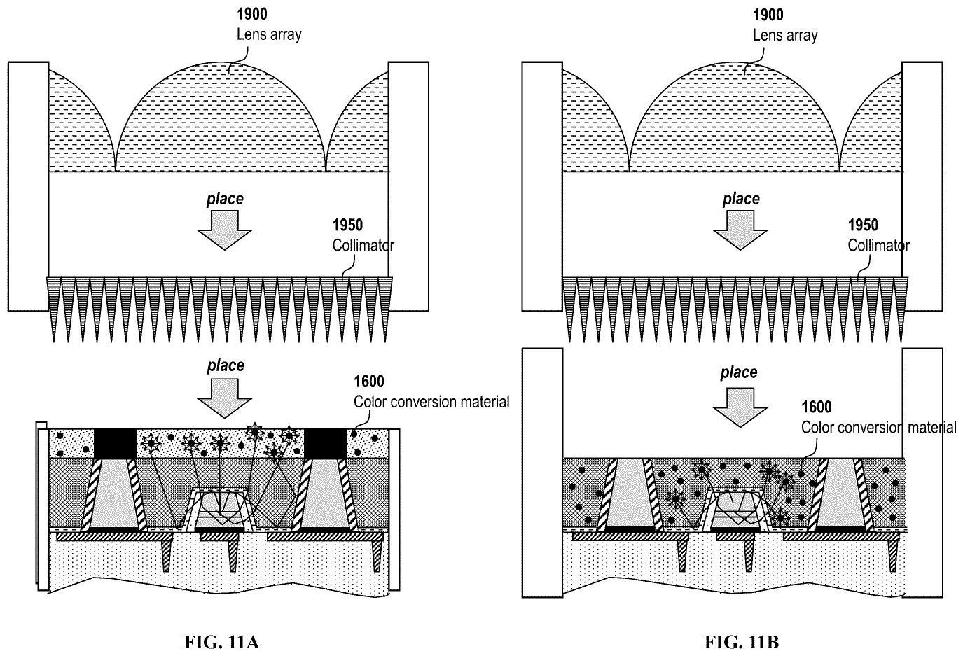

FIG. 10A to 10D illustrate various LED arrays according to embodiments of the present disclosure.

FIG. 10A illustrates an embodiment that includes a lens array 1900 on top of an LED array 1100. The lens array 1900 collimates photons. Collimation not only increases the luminance of the display device, but also increases the coupling efficiency between the display device and the optical system (i.e., relay optics) and can improve the depth of focus when implementing augmented reality (AR) and virtual reality (VR) display system.

FIG. 10B illustrates an embodiment in which the inside the cavity 1300 is filled with color conversion material 1605 and a lens array 1900 is provided on top of the LED array 1100.

FIG. 10C illustrates an embodiment in which a color conversion material 1605 is installed on top of the LED array 1100, and a black layer 1800 is installed between the color conversion material 1605 to prevent crosstalk and increase the contrast ratio.

FIG. 10D is an embodiment of installing a lens array 1900 on the top of color conversion material 1605 in addition to the embodiment of FIG. 10C.

When applying the color conversion material 1605 in the embodiments of the present disclosure, a color filter material and/or a distributed Bragg reflector (DBR) can be installed under the color conversion material 1605.

In this embodiment, color purity can be increased by blocking photons that are emitted directly from the LED emitter 1110 without interacting with the color conversion material 1605.

FIG. 11A to 11B illustrate another embodiments of the present disclosure with nano- to microscale optical collimator 1000 for collimation installed on top of the color conversion layer.

FIG. 11A is an embodiment in which a color conversion material 600 is installed on top of the LED array 1100, FIG. 11B is an embodiment in which a color conversion material 1605 is installed the inside the cavity 1300. As shown, the optical collimator 1950 is placed on top of the color conversion material 1605, and a lens array 1900 is placed thereon for further collimation.

The physics of color conversion material 1605 is based on the principle of down conversion, in which photons emitted from a light source interact with a quantum dot material to emit photons with a wavelength longer than the incident wavelength, and its radiation distribution is isotropic. The amount of forward and backward photons may be approximately equal.

As such, this distribution is inherently difficult to collimate, and collimation is only possible by using a lens (i.e., a refractive lens) that is much larger than the footprint of the color conversion material 1605. If collimation can only be done using a large lens like this, the pixel pitch becomes big, which becomes an obstacle to realizing a high-resolution display device with a small size.

Therefore, a two-stage collimation is required, with proper pre-collimation by some means, followed by additional collimation with the lens. The present disclosure proposes to place a nano to micro size optical element on the color conversion material 1605 for the purpose of pre-collimation. Examples of optical device that control the direction of light coming from a light source include optical cavity (i.e., microcavity) structures applied in laser technology, photonic crystals with materials of different refractive indices interposed at intervals smaller than the wavelength of visible light, and meta-lenses.

FIGS. 11A and 11B show example shapes of optical collimator 1950, which is a tapered structure in the downward direction, among many other shapes. As another examples, the cross-sectional shapes of collimator 1950 may include a circular or polygonal one, and the cross-section of the light exit portion may be wider than the light incident portion.

Although the present disclosure has been described with an exemplary embodiment, various changes and modifications may be suggested to one skilled in the art. It is intended that the present disclosure encompass such changes and modifications as fall within the scope of the appended claims.

1. A light-emitting device comprising:
a backplane;
a light emitting diode (LED) emitter attached to the backplane, the LED emitter comprising an LED emitting stack that is made of a semiconductor material, and comprises an n-type region and a p-type region and a quantum well therebetween; and
a light-reflecting partition attached to the backplane,
wherein
the light-reflecting partition is made of the semiconductor material;
the light-reflecting partition forms a cavity surrounding the LED emitter; and
a surface of the light-reflecting partition is coated with a first reflective layer.

2. The light-emitting device of claim 1, further comprising:
an LED array including:
a plurality of LED emitters arranged in an array, and
a plurality of light-reflecting partitions arranged a grid configuration.

3. The light-emitting device of claim 2, wherein
each of the plurality of light-reflecting partitions forms a cavity surrounding one of the plurality of LED emitters,
wherein the cavity is left as a free space or filled with a transparent polymer encapsulation material or a color conversion material.

4. The light-emitting device of claim 1, wherein
the first reflective layer is made of a light-reflective metallic film or a material of inorganic powder including titanium dioxide (TiO₂).

5. The light-emitting device of claim 4, wherein
the first reflective layer coated on each light-reflective partition is electrically conductive.

6. The light-emitting device of claim 2, wherein
a height of the plurality of LED emitters is a same as or lower than a height of the plurality of light-reflective partitions.

7. The light-emitting device of claim 1, further comprising
a second light-reflective layer formed on a top surface of the LED emitter.

8. The light-emitting device of claim 7, wherein
a shape of the second light-reflective layer includes one of various geometric shapes including a flat shape, concave shape, convex shape, and combinations thereof.

9. The light-emitting device of claim 7, wherein
the second light-reflective layer covers an n-contact of the LED emitter when the n-type region is disposed at an upper position and the p-type region is disposed at a lower position.

10. The light-emitting device of claim 7, wherein
the second reflective layer covers an entire upper part of the LED emitter.

11. The light-emitting device of claim 2, further comprising
a lens array located on top of the LED array.

12. The light-emitting device of claim 11, wherein
a color conversion layer is located on top of the LED array.

13. The light-emitting device of claim 12, wherein
both the color conversion layer and the lens array are located on a top of the LED array.

14. The light-emitting device of claim 1, wherein
a p-contact of the LED emitter is attached to a p-pad of the backplane, and
an n-contact of the LED emitter and an n-pad of the backplane are electrically connected by a conductive layer.

15. The light-emitting device of claim 1, wherein
an n-contact of the LED emitter is attached to an n-pad of the backplane, and
a p-contact of the LED emitter and a p-pad of the backplane are electrically connected by a conductive layer.

16. The light-emitting device of claim 1,
a nanoscale- to microscale optical collimator for collimation is located on top of the color conversion layer.

17. The light-emitting device of claim 16,
the optical collimator is tapered in a downward direction.

18. The light-emitting device of claim 17,
the optical collimator has one of cross-sectional shapes including a circular or polygonal one, and a cross-section of a light exit portion thereof is wider than that of a light incident portion thereof.
